(19) United States
(12) Patent Application Publication
(10) Pub. No.: US 2025/0201578 A1
(43) Pub. Date: Jun. 19, 2025

(54) STRUCTURES AND METHODS OF FORMING STRUCTURES

(71) Applicant: ASM IP Holding B.V., Almere (NL)

(72) Inventors: Debanjan Jana, Leuven (BE); David De Roest, Leuven (BE)

(21) Appl. No.: 18/976,442

(22) Filed: Dec. 11, 2024

Related U.S. Application Data
(60) Provisional application No. 63/609,890, filed on Dec. 14, 2023.

(51) Int. Cl. H01L 21/3205; H01L 21/311; H01L 21/762; H01L 21/768

(52) U.S. Cl. CPC H01L 21/32051; H01L 21/31105; H01L 21/76224; H01L 21/76877

(57) ABSTRACT

The disclosure relates to methods of forming a structure, to methods of decreasing a pitch of a feature on a semiconductor substrate, to methods of patterning a target layer, to methods of depositing material in a gap and to semiconductor processing assemblies. The methods comprise providing a patterned substrate comprising a gap in a reaction chamber, wherein the gap has a sidewall, and the sidewall is covered with spacer material. The method further comprises depositing a first metal in the gap by a vapor deposition method to fill the gap at least partially.

### CROSS-REFERENCE TO RELATED APPLICATIONS

The present application claims priority to and the benefit of U.S. Provisional Application No. 63/608,890, filed Dec. 14, 2024, the entirety of which is incorporated by reference herein.

### FIELD

The present disclosure generally relates to methods and assemblies for processing semiconductor substrates. More particularly, the disclosure relates to methods and assemblies for forming structures, such as metal lines. The methods may comprise selectively etching a particular material on a semiconductor substrate.

### BACKGROUND

Patterning semiconductor substrates to form structures and semiconductor devices thereon are multi-step processes, in which the properties of various materials—each selected to perform a function during the processing or in the final device—have to be considered. Any simplification, improved compatibility or uniformity during processing may have significant impact on the feasibility of a desired pattern or device structure. Further, decreasing of semiconductor device size requires the adoption of new patterning processes to enable the decrease in critical dimensions of adjacent structures. Therefore, new materials and their combinations are continuously sought after.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of forming a structure, methods of decreasing a pitch of a feature in a semiconductor substrate, methods of patterning a target layer and methods of depositing material in a gap. Embodiments of the current disclosure further relate to methods of fabricating semiconductor devices, and to semiconductor processing assemblies.

Various embodiments of the current disclosure relate to methods of forming a structure. The methods of forming structure comprise providing a patterned substrate comprising a gap in a reaction chamber, wherein the gap has a sidewall, and the sidewall is covered with spacer material. The method further comprises depositing a first metal in the gap by a vapor deposition method to fill the gap at least partially.

In some embodiments, the gap is formed between two primary mandrels. In some embodiments, the deposited first metal and the primary mandrel define a pattern.

In some embodiments, the gap comprises a bottom, and the bottom comprises different material than the sidewall. In some embodiments, the bottom is formed by a storage layer. In some embodiments, the bottom comprises silicon.

In some embodiments, the spacer material comprises silicon.

In some embodiments, the vapor deposition method is a cyclic vapor deposition method.

In some embodiments, the sidewall comprises a second metal. In some embodiments, the first metal and the second metal are the same. In some embodiments, the first metal is deposited at least partially as elemental metal. In some embodiments, the primary mandrel is formed substantially of the second metal.

In some embodiments, the gap has a width from about 5 nm to about 60 nm. In some embodiments, the gap has a depth from about 5 nm to about 50 nm.

In some embodiments, the thickness of the spacer material is substantially equal to the gap width to be filled by the first metal. In some embodiments, the spacer material is removed after depositing the first metal in the gap.

In some embodiments, the deposited first metal and primary mandrel form a mask for etching an underlaying material.

In an aspect, methods of decreasing a pitch of a feature in a semiconductor substrate are disclosed. The method of decreasing a pitch of a feature in a semiconductor substrate comprises providing a patterned substrate comprising a gap in a reaction chamber, wherein the gap has a sidewall, and the sidewall is covered with spacer material. The method further comprises depositing a first metal in the gap by a vapor deposition method to fill the gap at least partially.

In another aspect, methods of patterning a target layer are disclosed. The method of patterning a target layer comprises providing a patterned substrate comprising a gap in a reaction chamber, wherein the gap has a sidewall, and the sidewall is covered with spacer material. The method further comprises depositing a first metal in the gap by a vapor deposition method to fill the gap at least partially.

In yet another aspect, methods of depositing material in a gap are disclosed. The method of depositing material in a gap comprises providing a patterned substrate comprising a gap in a reaction chamber, wherein the gap has a sidewall, and the sidewall is covered with spacer material. The method further comprises depositing a first metal in the gap by a vapor deposition method to fill the gap at least partially.

In yet another aspect, a method of forming a structure is disclosed. The method comprising: forming a plurality of primary mandrels on a substrate; depositing a spacer material on sidewalls of the primary mandrels, the spacer material defining a plurality of gaps between adjacent primary mandrels; forming a plurality of second mandrels in the plurality of gaps; and removing the spacer material, thereby providing a pattern comprising at least the primary mandrels and the second mandrels. In an embodiment, the spacer material comprises silicon, and the primary mandrels and the second mandrels comprise molybdenum.

Methods according to the current disclosure may be used for manufacturing semiconductor devices. Thus, methods of manufacturing semiconductor devices are disclosed.

In a further aspect, a semiconductor processing assembly is disclosed. The semiconductor processing assembly comprises a reaction chamber and a controller and it is constructed and arranged to carry out a method as disclosed herein.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure.

In the drawings

FIG. 1 is a block diagram of exemplary embodiments of a method according to the current disclosure.

FIG. 2 is a schematic presentation of exemplary embodiments of a method according to the current disclosure.

FIG. 3 is a schematic drawing of an embodiment of a semiconductor processing assembly according to the current disclosure.

It will be appreciated that elements in the figures are illustrated for simplicity and clarity and have not necessarily been drawn to scale. The illustrations presented herein are not meant to be actual views of any particular material, structure, or device, but are merely idealized representations that are used to describe embodiments of the disclosure. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, and semiconductor processing assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The headings provided herein, if any, are for convenience only and do not necessarily affect the scope or meaning of the claimed subject-matter.

In an aspect, a method of forming a structure is disclosed. The method comprises providing a patterned substrate comprising a gap in a reaction chamber, wherein the gap has a sidewall, and the sidewall is covered with spacer material. The method further comprises depositing a first metal in the gap by a vapor deposition method to fill the gap at least partially.

The deposition method according to the current disclosure comprises providing a substrate in a reaction chamber. The substrate may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such as tungsten, ruthenium, molybdenum, cobalt, aluminum or copper, or metallic materials, crystalline materials, epitaxial, heteroepitaxial, and/or single crystal materials. In some embodiments, the substrate comprises silicon. The substrate may comprise other materials, as described above, in addition to silicon. The other materials may form layers. Specifically, the substrate may comprise a partially fabricated semiconductor device.

In some embodiments, the substrate may be pretreated or cleaned prior to or at the beginning of a deposition method according to the current disclosure. In some embodiments, the substrate may be subjected to a plasma cleaning process prior to or at the beginning of the deposition method. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the deposition method. In some embodiments, the substrate surface may be exposed to hydrogen plasma, radicals, or atomic species prior to or at the beginning of the deposition method. In some embodiments, a deposition method according to the current disclosure may be a selective deposition method. In some embodiments, a pretreatment or cleaning process may be carried out in the same reaction chamber as a selective deposition method. However, in some embodiments, a pretreatment or cleaning process may be carried out in a separate reaction chamber.

A substrate according to the current disclosure is a patterned substrate. A patterned substrate according to the current disclosure means a substrate comprising a pattern on or in it. For the purposes of the current disclosure, a pattern comprises a gap. A gap in this disclosure is in or on a substrate. A gap is to be understood to describe a change in the surface topology of the substrate leading to some areas of the substrate surface being lower than other areas. Gaps thus include topologies in which parts of the substrate surface are lower relative to the majority of the substrate surface. These include trenches, vias, recesses, valleys, crevices and the like. Further, also areas between elevated features protruding upwards of the majority of the substrate surface form gaps. Thus, the space between adjacent fins or pillars is considered a gap. A gap may comprise a top and a bottom. An upper part of a gap is the area at the opening of the gap, and the bottom of the gap is the part of the gap distal to the opening of the gap. The area outside the gap is termed the top surface of a gap, such as the topmost horizontal part of a fin or a pillar, or an area of the substrate between holes or vias. A sidewall is a surface connecting the top and the bottom of the gap.

A method of forming a structure according to the current disclosure comprises providing a patterned substrate in a reaction chamber. In other words, a substrate is in a space where the deposition conditions can be controlled. The reaction chamber may be a single wafer reactor. Alternatively, the reaction chamber may be a batch reactor. The reaction chamber can form part of a vapor processing assembly for manufacturing semiconductor devices. The vapor processing assembly may comprise one or more multi-station processing chambers. The reaction chamber may be part of a cluster tool in which different processes are performed to form an integrated circuit. Various phases of method can be performed within a single reaction chamber, or they can be performed in multiple reaction chambers, such as reaction chambers of a cluster tool, or deposition stations of a multi-station processing chamber.

In some embodiments, the reaction chamber may be a flow-type reactor, such as a crossflow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be single-wafer ALD reactor. In some embodiments, the reaction chamber may be a high-volume manufacturing single-wafer ALD reactor. In some embodiments, the reaction chamber may be a batch reactor for manufacturing multiple substrates simultaneously.

The reaction chamber can form part of an atomic layer deposition (ALD) assembly. The reaction chamber can form part of a chemical vapor deposition (CVD) assembly. The vapor deposition assembly may be an ALD or a CVD deposition assembly, but in certain process steps, MLD may also be employed in some parts of the deposition process flows. In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors.

In the current method, a first metal is deposited in the gap by a vapor deposition method to fill the gap at least partially. A vapor deposition method according to the current disclosure means processes in which material is deposited on the substrate from gas phase. In this disclosure, “gas” can include material that is a gas at normal temperature and pressure (NTP), a vaporized solid and/or a vaporized liquid, and can be constituted by a single gas or a mixture of gases, depending on the context. One or more precursors used to deposit the first metal (e.g., a first metal precursor) may be provided to the reaction chamber in gas phase. A first metal precursor may be provided to the reaction chamber in gas phase.

The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

In some embodiments, depositing the first metal comprises a cyclic deposition process (i.e. a cyclic vapor deposition method). Generally, in cyclic deposition processes according to the current disclosure, such as atomic layer deposition (ALD) and molecular layer deposition (MLD), during each cycle, a precursor is introduced to a reaction chamber and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, in some embodiments, another precursor or a reactant may be introduced into the reaction chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a first metal precursor into the reaction chamber. In some embodiments, the cyclic deposition process comprises purging the reaction chamber after providing an additional reactant, such as a reducing agent, into the reaction chamber. In some embodiments, the cyclic deposition process comprises purging the reaction chamber after providing a first metal precursor into the reaction chamber, and after providing an additional reactant into the reaction chamber. Without limiting the current disclosure to any specific theory, ALD and MLD may be similar processes in terms of self-limiting reactions and slower and more controllable layer growth speed compared to CVD. Generally, ALD is used to deposit inorganic materials, whereas in MLD, the precursors may be fully organic molecules.

The process may comprise one or more cyclic phases. In some embodiments, the process comprises or one or more non-cyclic (i.e. continuous) phases. In some embodiments, the deposition process comprises the continuous flow of at least one precursor. In such an embodiment, the process comprises a continuous flow of a first polymer precursor or a second polymer precursor. In some embodiments, one or more of the precursors are provided in the reaction chamber continuously.

CVD-type processes may be characterized by vapor deposition which is not self-limiting. They typically involve gas phase reactions between two or more precursors and/or reactants. The precursor(s) and reactant(s) can be provided simultaneously to the reaction space or substrate, or in partially or completely separated pulses. However, CVD may be performed with a single precursor, or two or more precursors that do not react with each other. The single precursor may decompose into reactive components that are deposited on the substrate surface. The decomposition may be brought about by plasma or thermal methods, for example. The substrate and/or reaction space can be heated to promote the reaction between the gaseous precursor and/or reactants. In some embodiments, the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap. In some embodiments, depositing the first metal comprises a CVD process.

In some embodiments, a method according to the current disclosure comprises a thermal deposition process. In thermal deposition, the chemical reactions are promoted by increased temperature relevant to ambient temperature. Generally, temperature increase provides the energy needed for the formation of the target material in the absence of other external energy sources, such as plasma, radicals, or other forms of radiation. In some embodiments, the method according to the current disclosure comprises a plasma-enhanced deposition method, for example PEALD or PECVD. For example, in some embodiments, the deposition may be performed by PEALD or PECVD.

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. Likewise, when the term “consisting essentially” is used referring to a chemical compound, substance, or composition of matter, it indicates that the chemical compound, substance, or composition of matter contains the components which are listed but can also containing trace elements and/or impurities that do not materially affect the characteristics of said chemical compound, substrate, or composition of matter. This notwithstanding, the chemical compound, substance, or composition of matter may, in some embodiments, comprise other components as trace elements or impurities, apart from the components that are listed.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

The term “essentially” as applied to a composition, a method, or a system generally means that the additional components do not substantially modify the properties and/or function of the composition, the method, or the system.

The term “substantially” as applied to a composition, a method, or a system generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly, it will be understood the term “under”, “underlying”, or “below” will be construed to be relative concepts.

The disclosure is further explained by the following exemplary embodiments depicted in the drawings. The illustrations presented herein are not meant to be actual views of any particular material, structure, or assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures, devices and assemblies depicted in the drawings may contain additional elements and details, which may be omitted for clarity.

For the sake of brevity, conventional manufacturing, connection, preparation, and other functional aspects of the methods and assemblies described herein may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

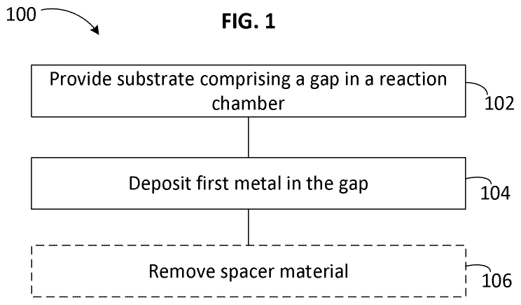

FIG. 1 is a block diagram of a method 100 according to the current disclosure. In phase 102, a patterned substrate comprising a gap is provided in a reaction chamber as disclosed herein. The gap may form a part of a partially fabricated semiconductor device. In some embodiments, the gap is formed between two primary mandrels. A primary mandrel may be a feature that is used for forming structures that may be narrower than achieved by EUV lithography techniques targeting feature pitch size from about 18 nm to about 14 nm. For example, in some embodiments, each mandrel defines a metal line in the final structure. In the current disclosure, a primary mandrel is formed though a patterning process preceding a method according to the current disclosure. A secondary mandrel in the current disclosure refers to a mandrel formed through a process as described herein. In some embodiments, the current methods are used to increase feature density on a semiconductor substrate, e.g., decreasing the pitch of metal lines. Thus, the primary mandrels and secondary mandrels may define the line density. In some embodiments, the primary mandrels and the secondary mandrels have substantially the same composition. Such embodiments may have the advantage that any subsequent etching is uniform, and the device fabrication process is simpler to optimize. As described above, a gap according to the current disclosure comprises a sidewall, and the sidewall is covered with spacer material. Various spacer materials are known in the art and are described in further detail below.

At block 104, the gap is at least partially filled with a first metal by using a vapor deposition method. The gap has a sidewall, and the sidewall is covered with spacer material. Thus, the gap width is a distance between two adjacent primary mandrels that are covered by the spacer material. The vapor deposition method may be an ALD method, a CVD method, such as a cyclic CVD method, or a hybrid having features of both ALD and CVD methods. In some embodiments, the gap is substantially filled with the first metal. The gap may be overfilled, and the excess first metal may be removed, and the structure planarized by chemical-mechanical polishing (CMP). In some embodiments, the deposition may be optimized so that no CMP phase is needed.

In embodiments, in which the gap is formed between two adjacent primary mandrels, depositing the first metal in the gap creates a secondary mandrel. The secondary mandrel is formed between the two primary mandrels, and the thickness of the spacer material determines the distance of the secondary mandrel to each of the primary mandrels. The width of the secondary mandrel is determined by the distance between the primary mandrels and the spacer material covering them.

As indicated in the optional block 106, in some embodiments, the spacer material is removed after depositing the first metal in the gap. The etching method is selected based on the properties of the spacer material from dry and wet etching techniques known in the art. Removal of spacer material will reveal the primary mandrels and the secondary mandrels, which together will form secondary gaps. The width of the secondary gaps is determined by the thickness of the spacer material. Manufacturing of the target devices may be continued by, for example, etching a bottom of the secondary gaps. In embodiments, in which the first metal is molybdenum, and the primary mandrels are formed of molybdenum, a second metal may also be provided, which may also be molybdenum, and the spacer material may advantageously be selected from silicon-containing materials, such as silicon oxide and silicon nitride. Silicon oxide and silicon nitride confer suitable etch contrast with molybdenum, and the materials further have better adhesion to each other than some alternative material combinations.

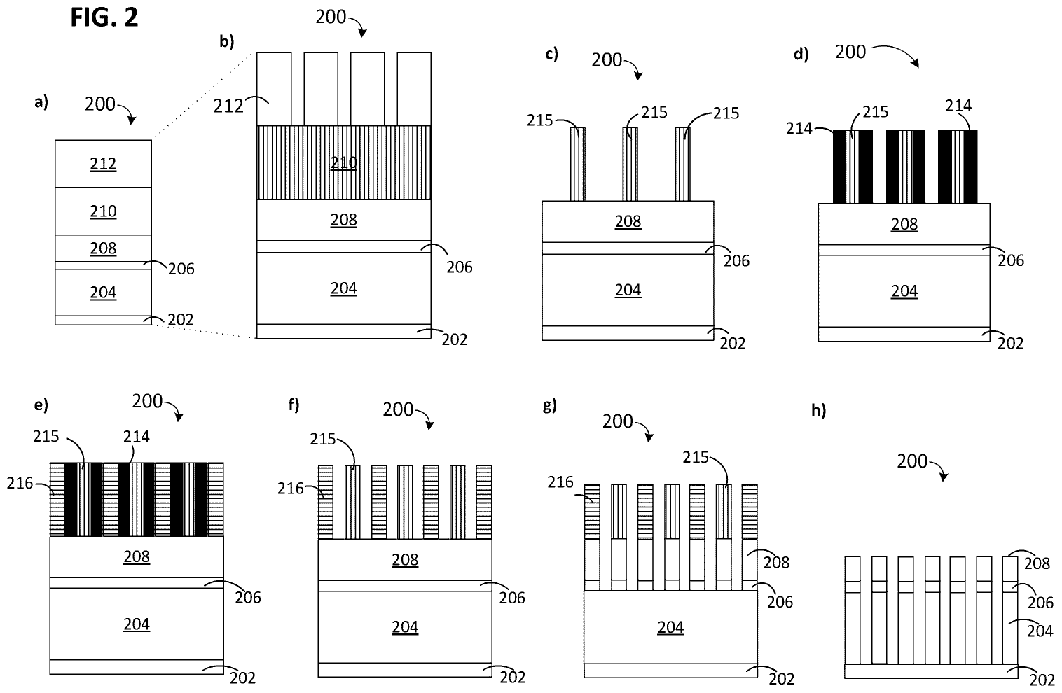

FIG. 2, panels a) to h), is a schematic presentation of a method according to the current disclosure. Several processing steps have been omitted from the figure for clarity, and each panel may indicate a result after multiple processing steps.

Panel a) depicts a partially fabricated semiconductor device 200. The bottom-most part in panel a), and in the subsequent panels, is the surface of a silicon substrate layer 202, on which multiple material layers have been formed. Depending on the intended device structure, layer 202 may also be a different type of a layer. The first layer on layer 202 is a metal layer, such as a ruthenium (Ru) layer 204, which will form metal lines after multiple processing steps. On top of the metal layer 204, is an optional adhesion layer 206, which may comprise, for example, titanium nitride (TiN). An adhesion layer is used for improving adhesion between the metal layer and the storage layer in embodiments, in which the adhesion is otherwise not sufficient. A storage layer 208 is positioned on the adhesion layer, and the storage layer may comprise silicon, for example, silicon oxide (SiO₂) or silicon nitride (SiN). A storage layer is a layer used in applications in which the etch contrast between the target patterning layer 210 and the metal layer 204 is not sufficient. The storage layer 208 serves to maintain the patterning of the target patterning layer 210 (e.g., one formed by primary and the secondary mandrels as described herein) after the target patterning layer is etched. The next layer in the embodiments of FIG. 2 is a target patterning layer 210, which may be a metal layer, such as a molybdenum layer. The target patterning layer 210 is covered by a hard mask 212. A hard mask may be formed of, for example, amorphous carbon, amorphous silicon, silicon oxide or silicon nitride. In panel a), the hard mask 212 has not been patterned. However, depending on the selected processing sequence, there may be additional layers on top of the hard mask 212, but they are omitted from the figure for brevity.

In panel b), an initial pattern for forming primary (e.g., first) mandrels 215 is formed in the hard mask 212.

In panel c) the hard mask 212 has been used to create the primary mandrels 215 according to the current disclosure, and the target patterning layer 210, such as a molybdenum layer, is represented by individual mandrels, e.g., primary mandrels 215, and the hard mask 212 has been removed using conventional methods.

In panel d), spacer material 214 has been formed on the mandrels 215. For example, spacer material can be deposited using ALD or MLD. In some embodiments, the spacer material 214 is deposited conformally. Conformal deposition by ALD may lead to a uniform thickness of the spacer material 214 throughout the structure. The initially deposited spacer material 214 may be removed by dry etching, for example. The transition from the processing stage presented in panel c) to the one presented in panel d) may require multiple steps, including deposition, etching, CMP or other cleaning steps. In some embodiments, the spacer material 214 comprises silicon. In some embodiments, the spacer material 214 comprises amorphous silicon. In some embodiments, the spacer material 214 consists essentially of, or consists of, amorphous silicon. In some embodiments, the spacer material 214 comprises silicon oxide. In some embodiments, the spacer material 214 consists essentially of, or consists of, silicon oxide. In some embodiments, the spacer material 214 comprises silicon nitride. In some embodiments, the spacer material 214 consists essentially of, or consists of, silicon nitride. In some embodiments, the spacer material 214 comprises titanium. In some embodiments, the spacer material 214 comprises titanium oxide. In some embodiments, the spacer material 214 consists essentially of, or consists of, titanium oxide. In some embodiments, the spacer material 214 comprises titanium nitride. In some embodiments, the spacer material 214 consists essentially of, or consists of, titanium nitride. In some embodiments, the spacer material 214 comprises titanium oxynitride. In some embodiments, the spacer material 214 consists essentially of, or consists of, titanium oxynitride. In some embodiments, the spacer material 214 comprises tungsten. In some embodiments, the spacer material 214 comprises tungsten carbide (WC). In some embodiments, the spacer material 214 consists essentially of, or consists of, carbide. In some embodiments, the spacer material 214 comprises tungsten nitride. In some embodiments, the spacer material 214 consists essentially of, or consists of, tungsten nitride. In some embodiments, the spacer material 214 comprises tungsten carbonitride. In some embodiments, the spacer material 214 consists essentially of, or consists of, tungsten carbonitride.

The composition and other characteristics of the spacer material 214 itself are not critical, as long as the sidewalls of the mandrels 215 can be uniformly covered by it at a desired thickness, and there is an etch contrast between the spacer material 214 on the one hand, and primary mandrels 215 and the secondary mandrels on the other. Thus, the spacer serves to define the distance (i.e. pitch) between a primary mandrel and a secondary mandrel.

The phase depicted in panel d) displays the gaps to be filled in the current method. As indicated above, in the methods according to the current disclosure, the sidewall is covered with spacer material 214. In other words, each gap is lined with spacer material 214, such as amorphous silicon, silicon oxide or silicon nitride. In some embodiments, such as the one depicted in panel d), the gap is formed between two primary mandrels 215.

Panel d) indicates an embodiment in which the gap comprises a bottom, and the bottom comprises different material than the sidewall. In some embodiments, the bottom of the gap comprises silicon. In some embodiments, the bottom of the gap comprises silicon oxide. In some embodiments, the bottom of the gap comprises silicon nitride. In some embodiments, such as in the embodiment of FIG. 2, the bottom of the gap is formed by a storage layer. A storage layer may be used in applications, in which the material of the primary mandrel and optionally the secondary mandrel.

The sidewall is formed by the metal, such as molybdenum, of the target patterning layer 210. Thus, in the embodiment of FIG. 2, the sidewall comprises a second metal. In some embodiments, the sidewall consists essentially of, or consists of, second metal. In some embodiments, the second metal is present as elemental metal. In some embodiments, the sidewall consists substantially only of, or consists of, elemental second metal. In the embodiment of FIG. 2, the primary mandrel 215 consists essentially of second metal. Thus, in some embodiments, the primary mandrel is formed substantially of the second metal. The second metal may be molybdenum. In some embodiments, the first metal is molybdenum, and the second metal is molybdenum. Such embodiments, in which the first metal and the second metal are the same, may have advantages for further fabrication steps of the target semiconductor device. In such embodiments, the primary and secondary mandrels may have substantially or entirely the same composition, which may allow uniform etching, and simplify the design and reliability of downstream processing. For example, the composition of a storage 208 layer may be easier to select when the composition of the primary mandrels and the secondary mandrels is the same.

The method according to the current disclosure further comprises depositing a first metal in the gap by a vapor deposition method to fill the gap at least partially. In some embodiments, the vapor deposition method is a cyclic vapor deposition method. The result of such deposition process is depicted in panel e) of FIG. 2. Panel e) shows the primary mandrels (215, vertical hatching), the secondary mandrels (216, horizontal hatching) deposited according to the current disclosure, and the spacer material (214, black) between every primary mandrel (215) and secondary mandrel (216).

In the embodiment of FIG. 2, the thickness of the primary mandrel, secondary mandrel and the spacer material is indicated to be substantially equal. Thus, in the embodiments of FIG. 2, the thickness of the spacer material is substantially equal to the gap width to be filled by the first metal. Further, the width of the primary mandrel is substantially equal to the thickness of the spacer material.

In some embodiments, the thickness of the primary mandrels and the secondary mandrels is substantially the same. In such embodiments, the primary mandrels and the secondary mandrels define metal lines of substantially equal width. The thickness of the spacer material 214 may be different from the thickness of the primary mandrels 215 and the secondary mandrels 216. Thus, in some embodiments, the spacer material is thicker than the width of the primary mandrels and the secondary mandrels. In some embodiments, the spacer material is thinner than the width of the primary mandrels and the secondary mandrels.

In some embodiments, the distance between primary mandrels 215 is from about 5 nm to about 60 nm, such as from about 10 nm to about 60 nm or from about 20 nm to about 60 nm, or from about 5 nm to about 30 nm or from about 5 nm to about 20 nm. In some embodiments, the distance between primary mandrels is about 30 nm. In some embodiments, the distance between primary mandrels is about 40 nm. In some embodiments, the distance between primary mandrels is about 50 nm. In some embodiments, the distance between primary mandrels is from about 30 to about 60 nm. In some embodiments, the distance between primary mandrels is from about 40 to about 60 nm. In some embodiments, the distance between primary mandrels is from about 20 to about 40 nm.

In some embodiments, the gap—e.g., the distance between adjacent layers of spacer material 214—has a width to depth ratio from about 1:1 to about 1:20.

In some embodiments, the thickness of the spacer material—defining the distance between metal lines in the final structure—is from about 1 nm to about 20 nm. For example, the thickness of the spacer material can be from about 5 nm to about 10 nm, such as about 6 nm or about 8 nm. Alternatively, for thin metal lines, thicknesses below 5 nm, such as 3 nm, can be envisaged. Conversely, forming thicker metal lines by the methods disclosed herein may have advantages in some applications.

In some embodiments, the width of the primary mandrels 215 is from about 4 nm to about 15 nm, such as from about 5 to about 10 nm. For example, the width of the primary mandrels 215 may be from about 7 nm to about 9 nm. In exemplary embodiments, the width of a primary mandrels 215 is about 7 nm, about 8 nm, about 10 nm or about 12 nm.

The width of the deposited metal that will form a secondary mandrel 216 is from about 4 nm to about 15 nm, such as from about 5 to about 10 nm, and it is selected independently from the width of the primary mandrels 215. For example, the width of a primary mandrel 215 may be from about 7 nm to about 9 nm. In exemplary embodiments, the width of a primary mandrel 215 is about 7 nm, about 8 nm, about 10 nm or about 12 nm.

The height of the primary mandrels and the secondary mandrels depends on the thickness of the target patterning layer 210. In some embodiments, the thickness of the target patterning layer 210 is from about 5 nm to about 60 nm, such as from about 10 nm to about 60 nm, such as about 15 nm, about 20 nm or about 30 nm, about 40 or about 50 nm. For example, the thickness of the target patterning layer 210 may be from about 5 nm to about 50 nm, or from about 5 nm to about 40 nm, or from about 5 nm to about 30 nm, or from about 30 nm to about 60 nm. In some embodiments, the gap has the same depth, i.e. from about 5 nm to about 60 nm, as the target patterning layer 210.

There are various options for depositing the first metal. For example, halogen containing metal precursors and metal-organic precursors are known in the art for depositing metal, such as molybdenum.

In some embodiments, the first metal precursor is selected from a group consisting of metalorganic precursors and inorganic precursors. In some embodiments, the first metal precursor comprises a metal halide. For example, the first metal precursor may be selected from a group consisting of NbCl₅, NbF₅, TaCl₅, TaF₅, TaI₅, TaBr₅, MoCl₅, MoCl₆, MoF₆, WCl₅, WCl₆ and WF₆.

In some embodiments, the first metal precursor comprises a metal oxyhalide. In some embodiments, the first metal precursor comprises an oxyhalide selected from a group consisting of MoOCl₄, MoO₂Cl₂, WOCl₄ and WO₂Cl₂.

In some embodiments, the first metal may comprise molybdenum, and molybdenum may be deposited utilizing a cyclic vapor deposition method, such as ALD. Therefore, depositing the first metal in the gap may comprise contacting the substrate alternatively and sequentially with a molybdenum precursor and a second vapor phase reactant, such as a reducing agent. In some embodiments, depositing the first metal may comprise depositing molybdenum by ALD, the deposition method comprising a deposition cycle which includes contacting the substrate with a vapor-phase molybdenum precursor and contacting the substrate with a second vapor phase reactant, such as a reducing agent. The reaction chamber may be purged after at least one of the molybdenum precursor and the second vapor-phase reactant.

In some embodiments, a deposition cycle for depositing a first metal (e.g. molybdenum) includes a first metal phase which comprises contacting substrate with a first vapor phase reactant comprising a molybdenum precursor. The terms “precursor” and “reactant” can refer to molecules (compounds or molecules comprising a single element) that participate in a chemical reaction that produces another compound or an element. A precursor typically contains portions that are at least partly incorporated into the compound or element resulting from the chemical reaction in question. Such a resulting compound or element may be deposited on a substrate. In some instances, a reactant is a precursor. In other instances, the compound or element that results from the chemical reaction does not contain a portion of the reactant (an element or group within the reactant) and therefore the reactant is not a precursor. In some embodiments, a precursor or a reactant is provided in a mixture of two or more compounds. In a mixture, the other compounds in addition to the precursor may be inert compounds or elements. In some embodiments, a precursor or a reactant is provided in a composition. Composition may be a solution or a gas in standard conditions. In the embodiments of the current disclosure, a first metal precursor is used to deposit a first metal in the gap. In some embodiments, the first metal is molybdenum, and correspondingly a molybdenum precursor is used.

In some embodiments, the molybdenum precursor may comprise molybdenum and a halogen, such as, for example, a chloride. In some embodiments, the molybdenum precursor may comprise molybdenum, a halogen and a chalcogen, wherein the chalcogen may comprise oxygen. In some embodiments, the molybdenum precursor comprises at least one of molybdenum pentachloride (MoCl₅) and molybdenum dichloride dioxide (MoO₂Cl₂). In some embodiments, the molybdenum precursor may be pulsed into the reaction chamber for a time period of less than 20 seconds, or less than 10 seconds, or less than 5 seconds or less than 1 second.

Excess first metal precursor (e.g., MoCl₅ or MoO₂Cl₂) and reaction byproducts (if any) may be removed from the substrate surface by purging with an inert gas. Excess second vapor phase reactant and any reaction byproducts may be removed with the aid of a vacuum generated by a pumping system.

The second phase of the deposition cycle for depositing a first metal, such as molybdenum, using an inorganic first metal precursor, the deposition cycle may comprise a metallization phase, in which the substrate is exposed to a second vapor phase reactant, such as one or more reducing agents which react with the molybdenum precursor or a derivative thereof present on the substrate thereby forming a first metal, such as elemental molybdenum. Therefore, in some embodiments of the disclosure, the second phase of the cyclical deposition cycle comprises contacting the semiconductor substrate with a reducing agent. The reducing agent maybe selected from a group consisting of molecular hydrogen (H₂), hydrogen radicals, hydrazine and derivatives of hydrazine, silane (SiH₄), disilane (Si₂H₆), trisilane (Si₃H₈), germane (GeH₄), digermane (Ge₂H₆), or diborane (B₂H₆). In some embodiments of the disclosure, the reducing agent may comprise hydrogen (H₂) or hydrogen radicals, atoms, or plasma, e.g., excited species of hydrogen created utilizing a hydrogen plasma, e.g., either a remote or direct plasma. In some embodiments, the reducing agent may comprise higher order silanes with the general empirical formula SiₓH₍₂ₓ₊₂₎. In some embodiments, the reducing agent may comprise higher order germanes with the general empirical formula GeₓH₍₂ₓ₊₂₎. In some embodiments, the reducing agent may be pulsed into the reaction chamber for time period of less than 20 seconds, or less than 10 seconds, or less than 5 seconds or less than 1 second. In some embodiments, the first metal precursor is MoO₂Cl₂, and the reducing agent is molecular hydrogen. In some embodiments, the first metal precursor is MoCl₅, and the reducing agent is molecular hydrogen.

In some embodiments, a first metal precursor is a molybdenum precursor, and the molybdenum precursor comprises a molybdenum atom and hydrocarbon ligand. In some embodiments, the molybdenum precursor comprises a metal-organic compound comprising molybdenum. Thus, the molybdenum precursor is a metal-organic precursor. By a metal-organic precursor is herein meant a molybdenum precursor comprising a molybdenum atom and a hydrocarbon ligand, wherein the molybdenum atom is not directly bonded to a carbon atom. In some embodiments, a metal-organic precursor comprises one molybdenum atom, which is not directly bonded with a carbon atom. In some embodiments, a metal-organic precursor comprises two or more molybdenum atoms, none of which is directly bonded to a carbon atom. In some embodiments, a metal-organic precursor comprises two or more metal atoms, wherein at least one metal atom is not directly bonded to a carbon atom.

In some embodiments, the molybdenum precursor comprises an organometallic compound comprising molybdenum. Thus, the molybdenum precursor is an organometallic precursor. By an organometallic precursor, it is herein meant a molybdenum precursor comprising a molybdenum atom and a hydrocarbon ligand, wherein the molybdenum atom is directly bonded to a carbon atom. In embodiments in which an organometallic precursor comprises two or more metal atoms, all of the metal atoms are directly bonded with a carbon atom. In some embodiments, molybdenum precursor comprises only molybdenum, carbon and hydrogen. In other words, in some embodiments, molybdenum precursor does not contain oxygen, nitrogen or other additional elements. In some embodiments, molybdenum precursor comprises at least two hydrocarbon ligands. In some embodiments, molybdenum precursor comprises at least three hydrocarbon ligands. In some embodiments, molybdenum precursor comprises four hydrocarbon ligands. In some embodiments, molybdenum precursor comprises a hydrocarbon ligand and a hydride ligand. In some embodiments, molybdenum precursor comprises a hydrocarbon ligand and two or more hydride ligands. In some embodiments, molybdenum precursor comprises two hydrocarbon ligands and two hydride ligands.

In some embodiments, molybdenum precursor comprises cyclic portions. For example, the molybdenum precursor may comprise one or more benzene rings. In some embodiments, the molybdenum precursor comprises two benzene rings. One or both benzene rings may comprise hydrocarbon substituents. In some embodiments, each benzene ring of the molybdenum precursor comprises an alkyl substituent. An alkyl substituent may be a methyl group, an ethyl group, or a linear or branched alkyl group comprising three, four, five or six carbon atoms. For example, the alkyl substituent of the benzene ring may be an n-propyl group or an iso-propyl group. Further, the alkyl substituent may be an n-, iso-, tert- or sec- form of a butyl, pentyl or hexyl moiety. In some embodiments, the molybdenum precursor comprises, consist essentially of, or consist of bis(ethylbenzene)molybdenum.

In some embodiments, the molybdenum precursor comprises a cyclopentadienyl (Cp) ligand. For example, the molybdenum precursor may comprise, consist essentially of, or consist of MoCp₂Cl₂ or MoCp₂H₂, Mo(iPrCp)₂Cl₂, Mo(iPrCp)₂H₂, or Mo(EtCp)₂H₂.

In some embodiments, the molybdenum precursor comprises a carbonyl group-containing ligand. For example, the molybdenum precursor may comprise, consist essentially of, or consist of Mo(CO)₆ or Mo(1,3,5-cycloheptatriene) (CO)₃. Additionally, in some embodiments, the molybdenum precursor comprises a nitrosyl group-containing ligand. For example, the molybdenum precursor may comprise, consist essentially of, or consist of MoCp(CO)₂(NO).

In embodiments, in which organometallic or a metal-organic first metal precursor is used, the metallization phase may comprise providing a reducing agent into the reaction chamber as described above. Alternatively, the metallization phase may comprise providing a halogenated reactant into the reaction chamber. The halogenated reactant may comprise a halogenated hydrocarbon. The halogenated hydrocarbon may comprise one halogen atom. The halogenated hydrocarbon may comprise one or more halogen atoms. The halogenated hydrocarbon may comprise two halogen atoms. The halogenated hydrocarbon may comprise two or more halogen atoms. The halogenated hydrocarbon may comprise three halogen atoms. The halogenated hydrocarbon may comprise three or more halogen atoms.

In some embodiments, the halogenated hydrocarbon comprises at least two halogen atoms attached to different carbon atoms. The reactant may comprise a hydrocarbon containing at least two carbon atoms attached to each other. The reactant may comprise three carbon atoms. Further, the reactant may comprise four, five or six carbon atoms. The reactant may comprise a linear, branched, cyclical and/or aromatic carbon chain. For example, the reactant may comprise a halogenated ethane, propane, 2-methylpropane, 2,2-dimethylpropane (neopentane), n-butane, 2-methylbutane, 2,2-dimethylbutane, n-pentane, 2-methylpentane, 3-methylpentane or an n-hexane. In some embodiments, the halogenated hydrocarbon comprises a halobenzene. In some embodiments, the halogenated hydrocarbon comprises a compound consisting of a halogen atom and a hydrocarbon group.

In some embodiments, the reactant comprises two or more halogen atoms, and at least two halogen atoms are attached to different carbon atoms. The halogen atoms may be the same halogen, for example bromine, iodine, fluorine or chlorine. Alternatively, the halogen atoms may be different halogens, such as iodine and bromine, bromine and chlorine, chlorine and iodine. The reactant may comprise two halogen atoms attached to different carbon atoms. The reactant may comprise three halogen atoms, each attached to a different carbon atom. The reactant may comprise four halogen atoms, each attached to a different carbon atom. Alternatively, in embodiments where the reactant comprises three, four or more halogen atoms, some carbon atoms may be attached to two or three halogen atoms.

In some embodiments, the two halogen atoms in the reactant are attached to adjacent carbon atoms of the hydrocarbon. Thus, the reactant may comprise two adjacent carbon atoms, each having at least one halogen substituent. In some embodiments, each of the adjacent carbon atoms has only one halogen substituent. Alternatively, one or both of the carbon atoms being attached to a halogen, may have two halogen atoms attached to it. Embodiments may be envisaged in which one or both of the carbon atoms being attached to a halogen, have three halogen atoms attached to it. The location of said two carbon atoms in a carbon chain may vary. In some embodiments, they are at the end of a carbon chain, but in some embodiments, they are located away from the end of a carbon chain. As is evident to those skilled in the art, the position of a given carbon atom in a carbon chain limits the number of potential substituents available.

For example, in embodiments, where the reactant comprises two carbon atoms, at least one halogen atom is attached to each carbon. If a two-carbon reactant comprises two halogen atoms, then each of them is attached to a different carbon atom. In embodiments where the reactant comprises two carbon atoms and three halogens, one of the carbon atoms is doubly substituted with a halogen. In embodiments where the reactant comprises two carbon atoms and four halogens, both of the carbon atoms may be doubly substituted with a halogen. Alternatively, one carbon atom may have one halogen substituent, whereas the second may have three.

Similarly, in embodiments where the reactant comprises three carbon atoms and two halogen atoms, each halogen atom is attached to a different carbon atom. Thus one carbon atom does not have a halogen atom attached to it. Two halogen atoms may be attached to neighboring carbon atoms (i.e. carbon atoms adjacent to each other in a carbon chain). Alternatively, there may be one carbon atom between the halogenated carbon atoms. For example, reactant may comprise, consist essentially of, or consist of 1,2-dihalopropane or 1,3-dihalopropane, such as 1,2-dichloropropane, 1,3-dichloropropane, 1,2-diiodopropane or 1,3-diiodopropane, 1,2-difluoropropane or 1,3-difluoropropane.

In embodiments where the reactant comprises three carbon atoms and three halogen atoms, each carbon atom may have a halogen atom attached to it. Alternatively, any one of the three carbon atoms may have two halogen atoms attached to it, and one carbon atom—either at the end of the carbon chain or in the middle of it—may be without a halogen. The doubly substituted carbon atom may be at the end of the carbon chain or in the middle of it. As a further alternative, in some embodiments, a three-carbon reactant may contain four halogen atoms. In such embodiments, each carbon may have a halogen atom attached to it, and one carbon—either at the end of the carbon chain or in the middle of it—may have an additional halogen atom attached to it. As a still further alternative, two of the carbons may have two halogen atoms attached to it, whereas one carbon atom—either at the end of the carbon chain or in the middle of it—may be without a halogen. In some embodiments, the reactant comprises 1,2-dihaloalkane or 1,2-dihaloalkene or 1,2-dihaloalkyne or 1,2-dihaloarene, where the halogens are attached to adjacent carbon atoms.

In some embodiments, a reactant has a general formula XₐR_{b}C—(CX_{c}R″_{d})ₙ—CXₐR′_{b}, wherein X is halogen, R, R′ and R″ are independently H or an alkyl group, a and b are independently 1 or 2, so that for each carbon atom a+b=3, n is 0, 1, 2, 3, 4 or 5, and wherein c and d are independently 0, 1 or 2, so that for each carbon atom c+d=2.

In some embodiments, a reactant has a general formula XₐR_{b}C—CXₐR′_{b}, wherein X is halogen, R and R′ are independently H or an alkyl group, a and b are independently 1, 2 or 3 so that for each carbon atom a+b=3.

In embodiments in which the reactant comprises four carbon, there may be two, three, four, five or six halogen substituents attached to the carbons. For example, the reactant may have a formula CH₃—CXH—CH₂—CXH₂, CH₃—CH₂—CXH—CXH₂, CH₃—CXH—CXH—CH₃ or H₂CX—CH₂—CH₂—CXH₂. In embodiments where the four-carbon halogen comprises three carbons, the reactant may have a formula such as H₂CX—CXH—CH₂—CXH₂, H₂CX—CXH—CXH—CH₃, HCX₂—CXH—CH₂—CH₃, HCX₂—CH₂—CXH—CH₃ or HCX₂—CH₂—CH₂—CXH₂ or CH₃—CXH—CX₂—CH₃. In the formulas, X represents a halogen. Examples of such reactants are 1,2-dihalobutane, 1,3-dihalobutane and 1,4-dihalobutane.

A cyclic or an aromatic reactant may be used in some embodiments. In some embodiments, reactant comprises a cyclic or an aromatic compound. In some embodiments, the halogenated hydrocarbon comprises an aryl group. In some embodiments, the halogenated hydrocarbon comprises iodobenzene or 1-iodobutane. In some embodiments, the halogenated hydrocarbon comprises bromobenzene or 1-bromobutane.

A reactant may comprise a di-halogenated benzene ring. The benzene ring may comprise two or more halogens. The benzene ring may contain additional substituents, such as one or more alkyl groups as described above. A reactant may comprise, consist essentially of, or consist of a di-halogenated benzene, such as 1,2-dibromobenzene, 1,2-diiodobenzene or 1,2-dichloroobenzene. The di-halogenated benzene, may also be a 1,3-dihalogenated or a 1,4-dihalogenated benzene. Further, a tri-halogenated benzene, such as 1,2,3- or 1,2,4-halogenated benzene is possible. An aromatic reactant may comprise four, five or six halogens. Cyclical reactants may comprise a cyclopentane or a cyclohexane, for example. A cyclical reactant may comprise two or more halogens. For example, a cyclohexane may contain up to twelve halogens, which may be the same or different. The halogens may be situated in cis- or trans-configuration. The halogens in a cyclohexane may be located in carbon positions 1 and 2, 1 and 3, 1 and 4, or 1, 2, 3 or 1, 2, 4. Examples of cyclic reactants are 1,2-diiodocyclohexane, 1,3-diiodocyclohexane, 1,4-diiodocyclohexane, 1,2-dibromocyclohexane, 1,3-dibromocyclohexane, 1,4-dibromocyclohexane, 1,2-difluorocyclohexane, 1,3-difluorocyclohexane, or 1,4-difluorocyclohexane

In some embodiments, the reactant has a general formula XₐR_{b}C—CXₐR′_{b}, wherein X is halogen, R and R′ are independently H or an alkyl group, a and b are independently 1 or 2, so that for each carbon atom a+b=3. In some embodiments, X is iodine. In some embodiments, X is bromine. In some embodiments, X is chlorine. In some embodiments, a is 1 for both carbon atoms. In some embodiments a is 1 for one carbon atom, and 2 for the other carbon atom. In some embodiments, R and R′ are both H.

In some embodiments of the disclosure, the first metal may be deposited to a thickness such that the gap between the spacer material 214 covering the sidewalls of the primary mandrels 215 is substantially completely filled with the first metal. For example, in some embodiments, the first metal may comprise molybdenum deposited to a thickness of between approximately 2 nm and 30 nm or between approximately 5 nm and 20 nm. In some embodiments, it may not be necessary to fill the gap with the first metal. A suitable thickness depends on the following processing steps, and as long as the targeted patterning of the underlying layers is achieved, a partially filled gap may be sufficient.

In some embodiments, the substrate may be heated to a desired deposition temperature during the deposition of the first metal. Thus, the deposition method for the deposition of the first metal, such as an ALD method, may be performed at a substrate temperature of less than approximately 500° C., or less than approximately 450° C., or less than approximately 400° C., or less than approximately 350° C., or less than approximately 300° C., or less than approximately 250° C., or even less than approximately 200° C. In some embodiments, the deposition of the first metal may be performed at a substrate temperature of between 300° C. and 450° C., or between 200° C. and 350° C., or between 200° C. and 500° C.

In additional embodiments, the reaction chamber in which the atomic layer deposition of the first metal takes place may be placed under a vacuum utilizing a pumping system fluidly connected to the reaction chamber. Therefore, in some embodiments, the ALD method for depositing the first metal layer may take place at reaction chamber pressure of less than 100 Torr, or less than 50 Torr, or less than 20 Torr, or less than 10 Torr.

In some embodiments, the first metal deposited in the gap by a cyclic vapor deposition method, such as ALD, may be deposited to completely fill the gap. In some embodiments, the step coverage of the first metal may be equal to or greater than about 50%, or greater than about 80%, or greater than about 90%, or greater than about 95%, or greater than about 98%, or greater than about 99%, or even about 100% in structures having aspect ratios (height to width) of about 2, or more than about 2, or more than about 5, or more than about 10, or more than about 25, or more than about 30.

In some embodiments, the first metal is deposited at least partially as elemental metal. In some embodiments, the first metal is deposited substantially as elemental metal. For example, the first metal, such as molybdenum, may comprise less than about 20 atomic % oxygen, less than about 10 atomic % oxygen, less than about 5 atomic % oxygen, or even less than about 2 atomic % oxygen. In further embodiments, the first metal may comprise less than about 10 atomic % hydrogen, or less than about 5 atomic % of hydrogen, or less than about 2 atomic % of hydrogen, or even less than about 1 atomic % of hydrogen. In some embodiments, the first metal may comprise less than about 10 atomic % halogen, such as Cl, or less than about 5 atomic % halogen, less than about 1 atomic % halogen, or less than about 0.5 atomic % halogen. In yet further embodiments, the first metal, such as molybdenum, may comprise less than about 10 atomic % carbon, or less than about 5 atomic % carbon, or less than about 2 atomic % carbon, or less than about 1 atomic % of carbon, or less than about 0.5 atomic % carbon. The elemental composition of the deposited materials may be measured by methods known to those skilled in the art of semiconductor materials development.

In some embodiments, after the first metal has been deposited in the gap, the spacer material 214 is removed, and the deposited first metal forms secondary mandrels. Panel f) of FIG. 2 depicts the partially fabricated semiconductor device 200 after the spacer material 214 has been removed. In some embodiments, the deposited first metal and the primary mandrel, forming the secondary mandrel, transfer the pattern into the underlying layer. In some embodiments, the deposited first metal and primary mandrel form an etching mask for etching an underlying material. By an underlying material is herein meant any material or materials on which the primary mandrel and the deposited first metal (“secondary mandrels”) were formed. For example, the underlying material may be a storage layer. In some embodiments, the primary mandrels 215 are formed of second metal, and there is an etch contrast between the first and second metal on the one hand, and the underlying layer. Thus, the underlying layer is etched faster relative to the first metal and second metal. The metal line pattern to be formed is visible as the primary mandrels 215 and the secondary mandrels 216. The spacer material 214 may be removed by methods known in the art of semiconductor device manufacturing. For example, plasma-based etching methods, such as wet etching or dry etching methods known in the art may be used.

The primary mandrels 215, and the secondary mandrels 216 formed by the current method may have the same or similar etching properties, in case their material is the same or similar. For example, the primary mandrels may be formed, of a second metal, as in the embodiment of FIG. 2. Both first metal and second metal may be molybdenum, and both primary mandrels 215 and secondary mandrels 216 may consist substantially of elemental molybdenum.

Panels g) and h) of FIG. 2 depict downstream processing steps of the semiconductor device manufacturing process according to the current disclosure. In panel g), etching continues towards forming the metal lines, and the adhesion layer 206 and the storage layer 208 have already been etched. Correspondingly, the primary mandrels 215 and secondary mandrels 216 have also been partially etched. In the process, the primary mandrels 215 and secondary mandrels 216 have been partially etched. In panel h), the etching process has been continued to the end, and the primary mandrels 215 and the secondary mandrels 216 have been fully etched away. In the absence of the mandrels 215, 216, the storage layer 208 has continued to define the pattern.

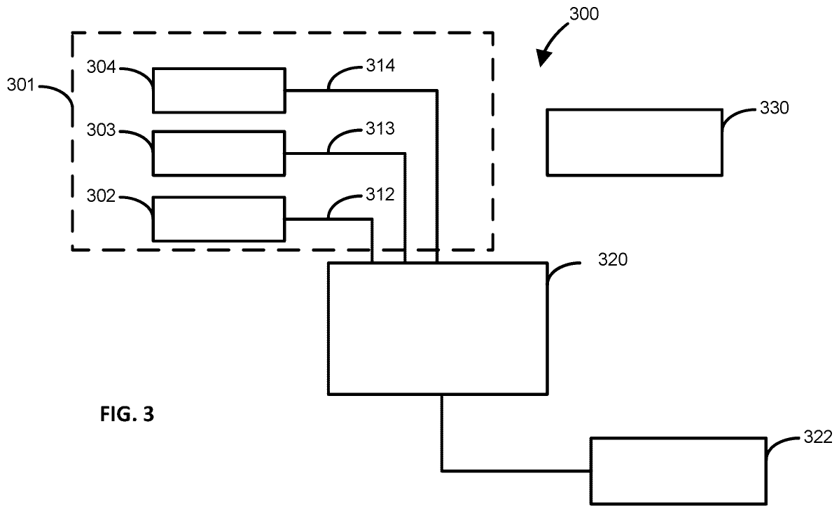

FIG. 3 is a schematic drawing of an embodiment of a semiconductor processing assembly 300 according to the current disclosure. The semiconductor processing assembly 300 comprises one or more reaction chambers 320 constructed and arranged to hold the substrate, a precursor injector system 301 constructed and arranged to provide a first metal precursor and a second reactant into the reaction chamber 320 in a vapor phase. The semiconductor processing assembly 300 further comprises a first metal precursor source vessel 302 constructed and arranged to contain the first metal precursor. The semiconductor processing assembly 300 further comprises a second reactant source vessel 303 constructed and arranged to contain the second reactant. The semiconductor processing assembly 300 is constructed and arranged to provide the first metal precursor and the second reactant via the precursor injector system 301 into the reaction chamber 320 for depositing a first metal in a gap of a substrate.

In some embodiments, the semiconductor processing assembly 300 further comprises one or more additional precursor source vessels 304, and the precursor injector system 301 is constructed and arranged to provide the one more additional precursor into the reaction chamber 320 in a vapor phase. The processing assembly 300 may comprise optional further source vessels constructed and arranged to contain additional reactants used in the processing of the substrate. For example, a further source vessel (not depicted) may be constructed and arranged to hold an etchant or a cleaning agent, for example.

The semiconductor processing assembly 300 can be used to perform a method as described herein. In the illustrated example, processing assembly 300 includes one or more reaction chambers 320, a precursor injector system 301, source vessels 302, 303, 304, optional and further source vessels, an exhaust source 322, and a controller 330. The processing assembly 300 may comprise one or more additional gas sources (not shown), such as an inert gas source, a carrier gas source and/or a purge gas source. Although illustrated with three source vessels 302-304, a processing assembly 300 can include any suitable number of source vessels. Source vessels 302-304 can be coupled to reaction chamber 320 via lines 312-314, which can each include flow controllers, valves, heaters, and the like. In some embodiments, each of the source vessels 302-304 may be independently heated or kept at ambient temperature. In some embodiments, a source vessel is heated so that a precursor or a reactant reaches a suitable temperature for vaporization. Reaction chamber 320 can include any suitable reaction chamber, such as an ALD or CVD reaction chamber as described herein. The exhaust source 322 can include one or more vacuum pumps.

Controller 330 includes electronic circuitry and software to selectively operate valves, manifolds, heaters, pumps and other components included in the processing assembly 300. Such circuitry and components operate to introduce precursors, reactants and other gases from the respective sources. Controller 330 can control timing of gas pulse sequences, temperature of the substrate and/or reaction chamber 320, pressure within the reaction chamber 320, and various other operations to provide proper operation of the processing assembly 300. Controller 330 can include control software to electrically or pneumatically control valves to control flow of precursors, reactants and other gases into and out of the reaction chamber 320. Controller 330 can include modules such as a software or hardware component, which performs certain tasks.

Other configurations of processing assembly 300 are possible, including different numbers and kinds of precursor and source vessels. For example, a reaction chamber 320 may comprise more than one, such as two or four, deposition stations. Such a multi-station configuration may have advantages if, for example, deposition of various materials and/or etching may be performed in the same reaction chamber. Further, it will be appreciated that there are many arrangements of valves, conduits, precursor sources, and reactant sources that may be used to accomplish the goal of selectively and in coordinated manner feeding gases into reaction chamber 320. Further, as a schematic representation of a processing assembly 300, many components have been omitted for simplicity of illustration, and such components may include, for example, various valves, manifolds, purifiers, heaters, containers, vents, and/or bypasses.

During operation of processing assembly 300, substrates, such as semiconductor wafers (not illustrated), are transferred from, e.g., a substrate handling system to reaction chamber 320. Once substrate(s) are transferred to reaction chamber 320 (i.e. they are provided in the reaction chamber 320), one or more gases from gas sources, such as precursors, reactants, carrier gases, and/or purge gases, are introduced into reaction chamber 320 to carry out the methods described herein.

In an aspect, a method of decreasing a pitch of a feature in a semiconductor substrate is disclosed. The method of decreasing a pitch of a feature in a semiconductor substrate comprises providing a patterned substrate comprising a gap in a reaction chamber, wherein the gap has a sidewall, and the sidewall is covered with spacer material. The method further comprises depositing a first metal in the gap by a vapor deposition method to fill the gap at least partially.

In an aspect, a method of patterning a target layer is disclosed. The method of patterning a target layer comprises providing a patterned substrate comprising a gap in a reaction chamber, wherein the gap has a sidewall, and the sidewall is covered with spacer material. The method further comprises depositing a first metal in the gap by a vapor deposition method to fill the gap at least partially.

In an aspect, a method of depositing material in a gap is disclosed. The method of depositing material in a gap comprises providing a patterned substrate comprising a gap in a reaction chamber, wherein the gap has a sidewall, and the sidewall is covered with spacer material. The method further comprises depositing a first metal in the gap by a vapor deposition method to fill the gap at least partially.

Methods according to the current disclosure may be used for manufacturing semiconductor devices. Thus, methods of manufacturing semiconductor devices are disclosed.

In a further aspect, semiconductor processing assembles for performing methods according to the current disclosure are disclosed.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject-matter of the present disclosure includes all novel and nonobvious combinations and sub-combinations of the various methods and assemblies, and other features, functions, acts, and/or properties disclosed herein, as well as any and all equivalents thereof.

1. A method of forming a structure, the method comprising:
providing a patterned substrate comprising a gap in a reaction chamber, the gap having a sidewall, wherein the sidewall is covered with spacer material; and
depositing a first metal in the gap by a vapor deposition method to fill the gap at least partially.

2. The method of claim 1, wherein the gap is formed between two primary mandrels.

3. The method of claim 2, wherein the sidewall comprises a second metal, and wherein the primary mandrel is formed substantially of the second metal.

4. The method of claim 2, wherein the deposited first metal and the primary mandrels define a pattern.

5. The method of claim 2, wherein the deposited first metal and primary mandrels form a mask for etching an underlaying material.

6. The method of claim 1, wherein spacer material comprises silicon.

7. The method of claim 1, wherein the vapor deposition method is a cyclic vapor deposition method.

8. The method of claim 1, wherein the sidewall comprises a second metal.

9. The method of claim 8, wherein the first metal and the second metal are the same.

10. The method of claim 1, wherein the gap comprises a bottom, and the bottom comprises different material than the sidewall.

11. The method of claim 10, wherein the bottom is formed by a storage layer.

12. The method of claim 10, wherein the bottom comprises silicon.

13. The method of claim 1, wherein the first metal is deposited at least partially as elemental metal.

14. The method of claim 1, wherein the gap has a width from about 5 nm to about 60 nm.

15. The method of claim 1, wherein the gap has a depth from about 5 nm to about 60 nm.

16. The method of claim 1, wherein a thickness of the spacer material is substantially equal to the gap width to be filled by the first metal.

17. The method of claim 1, wherein the spacer material is removed after depositing the first metal in the gap.

18. A method of forming a structure, the method comprising:
forming a plurality of primary mandrels on a substrate;
depositing a spacer material on sidewalls of the primary mandrels, the spacer material defining a plurality of gaps between adjacent primary mandrels;
forming a plurality of second mandrels in the plurality of gaps; and
removing the spacer material, thereby providing a pattern comprising at least the primary mandrels and the second mandrels.

19. The method of claim 18, wherein the spacer material comprises silicon, and wherein the primary mandrels and the second mandrels comprise molybdenum.
